(19) United States
(12) Patent Application Publication
(10) Pub. No.: US 2026/0314147 A1
(43) Pub. Date: Oct. 8, 2026

(54) LED ELECTRODE ASSEMBLY AND METHOD FOR MANUFACTURING THEREOF

(71) Applicant: Kookmin University Industry Academy Cooperation Foundation, Seoul (KR)

(72) Inventor: Young Rag Do, Seoul (KR)

(73) Assignee: Kookmin University Industry Academy Cooperation Foundation, Seoul (KR)

(21) Appl. No.: 19/575,797

(22) Filed: Mar. 23, 2026

(30) Foreign Application Priority Data
Mar. 24, 2025 (KR) 10-2025-0037438

(51) Int. Cl. H10H 29/80; H10H 29/01; H10H 29/24

(52) U.S. Cl. CPC H10H 29/8321; H10H 29/032; H10H 29/24

(57) ABSTRACT

The present invention relates to an LED electrode assembly and a manufacturing method therefor. The present invention is useful as a method capable of simply vertically assembling LED elements having various shapes and sizes in a desired direction in a desired area, thereby simplifying the process and reducing process time and cost, and wherein the alignment directionality of the LED elements assembled in a desired area may be assembled in a desired direction, thereby making it suitable for manufacturing various light-source products ranging from displays requiring high-resolution and high-brightness characteristics to lighting and the like.

### CROSS-REFERENCE TO RELATED APPLICATIONS

The present application claims priority under 35 U.S.C. § 119(a) to Korean patent application number 10-2025-0037438, filed on Mar. 24, 2025, in the Korean Intellectual Property Office, the entire disclosure of which is incorporated herein by reference.

### DESCRIPTION OF THE INVENTION

### Technical Field

The present invention relates to an LED electrode assembly and a manufacturing method therefor.

### BACKGROUND OF THE INVENTION

Recently, demand for various LED displays such as AR and VR using micro LED has increased and development has accelerated, but it remains challenging to develop technologies for transferring and pixelating LED CHIPs of various sizes, which are essential for implementing LED displays that provide high brightness and ultra-high-resolution images.

Recently, technologies such as elastic stamp methods, roll-to-roll methods, laser lift-off methods, and electrostatic/electronic transfer methods have been developed to transfer and pixelate LED CHIPs, but these methods are also inefficient in terms of transfer time and yield, and when the size of LED CHIPs becomes less than 10 μm, they have difficulty achieving satisfactory transfer performance.

In addition, a self-alignment method of micro/nano LED using dielectrophoretic force has been developed, but the method is limited in terms of the shape of an LED element and it is not easy to secure vertical alignment in which the elements are mounted on electrodes in the thickness direction. In addition, although the method using dielectrophoretic force can align LED on electrodes forming electric fields, it is difficult to locally position them at specific parts of the electrodes forming the electric field. In addition, the method using dielectrophoretic force requires installation of two assembly electrodes separated from each other for forming electric fields, thereby causing additional space allocation, process time and cost.

Accordingly, there is an urgent need to develop transfer and pixelization techniques for LED elements that enable simple mounting of individual LED of various sizes and shapes at desired locations and desired directions while improving vertical assembly yields.

### SUMMARY OF THE INVENTION

### Problem to be Solved

The present invention has been made in an effort to solve the above problems and provides a manufacturing method for an LED electrode assembly capable of vertically assembling LED elements having various sizes and shapes into a desired area in a desired direction by using a simple method, and an LED electrode assembly implemented through the same.

In addition, the present invention provides a manufacturing method for an LED electrode assembly and an LED electrode assembly implemented thereby, which can improve the ratio and number of elements vertically assembled in a desired direction within a desired area.

Further, another object of the present invention is to provide a light source for high-resolution and high-brightness displays using the LED electrode assembly according to the present invention.

### Means for Solving the Problem

In order to solve the above problems, the present invention provides a manufacturing method for an LED electrode assembly, including: (1) preparing a first electrode on which one end of an organic coupling linker having metal-binding groups at both ends is bound to a surface; (2) treating, on the first electrode on which the organic coupling linker is disposed, an LED element dispersion solution comprising LED elements whose layers are stacked in a thickness direction with one side being a metal electrode layer, and a solvent; (3) forming a bond between the remaining metal-binding group in the organic coupling linker bound to the first electrode surface and the metal electrode layer in the LED element so as to vertically assemble the LED element on the first electrode; and (4) forming a second electrode to be in electrical contact with an upper portion of the vertically assembled LED element; wherein, in step (2), the solvent is configured such that the LED element dispersion solution forms droplets on the first electrode with a contact angle of 10 to 72 degrees.

According to an embodiment of the present invention, the metal-binding group may include one or more of a thiol group and an amine group.

In addition, the solvent may have a surface tension of 26 mN/m or more measured at 20° C.

In addition, the first electrode surface on which the LED elements are mounted and a metal layer of the LED element may each independently include one or more selected from among gold, silver, copper, and alloys including any one or more thereof.

In addition, in step (1), the organic coupling linker may form a self-assembled monolayer (SAM) on the first electrode surface.

In addition, the solvent may have a vapor pressure of 10 mmHg or less at the temperature for performing step (3).

In addition, the method may further include, between steps (3) and (4), a heat treatment step performed at 200 to 600° C. for 3 to 10 minutes, and a cleaning step of washing the first electrode surface in order to remove misaligned LED elements from the first electrode surface.

The present invention also provides an LED electrode assembly comprising a plurality of first electrodes spaced apart from each other; a plurality of LED elements including first LED elements that have a metal electrode layer on one side in a thickness direction where layers are stacked, the metal electrode layer being vertically assembled to contact an upper surface of the first electrode; and a second electrode electrically contacting upper portions of the vertically assembled LED elements, wherein an organic coupling linker having metal-binding groups at both ends or a carbonized material thereof is provided between the first electrode and the metal electrode layer of the first LED element contacting the first electrode.

According to an embodiment of the present invention, the number of first LED elements among all LED elements positioned per 10,000 μm² in the first electrode may be 40 or more, and the proportion of the first LED elements may be 80% or more.

In addition, the LED element has a thickness of 0.5 to 3 μm and an area of a surface perpendicular to the thickness direction may be in a range from 0.25 to 100 μm².

In addition, the number of first LED elements among all LED elements positioned per 10,000 μm² in the first electrode may be 60 or more and a ratio of the first LED element may be 80% or more.

The present invention also provides a light source including a substrate having a plurality of sub-pixel sites and an LED electrode assembly according to one embodiment of the present invention disposed in each of the sub-pixel sites.

Hereinafter, the terms used in the present invention will be defined.

In the description of embodiments of the present disclosure, when it is stated that each layer, region, pattern, or substrate, or any “on”, “above”, “over”, “below”, “under”, “lower”, or “bottom” of each layer, region, or pattern is formed, the terms “on”, “above”, “over”, “below”, “under”, “lower” and “bottom” include both the meanings of “directly” and “indirectly”.

Meanwhile, it is disclosed that the present disclosure was invented with the support of the following national research and development project.

[Assignment Unique Number]2710076063

[Assignment Number] NR059326 (A2025-0148)

[Name of the Ministry] Korea Ministry of Science and ICT

[Name of the Assignment Managing (Professional) Organization] National Research Foundation of Korea

[Research Project Title] Individual Basic Research (MSIT)

[Project Name] Development of Fundamental/Applied Technology for Dot-LED Materials & Display

[Project Implementing Organization] Kookmin University

[Research Period] Mar. 1, 2025-Feb. 28, 2026

### Effects of the Invention

The manufacturing method for an LED electrode assembly according to the present invention is useful as a method capable of simply vertically assembling LED elements having various shapes and sizes in desired directions in a desired area, thereby simplifying processes and reducing process time and cost. In addition, the alignment directionality of the LED elements assembled in a desired area may increase the proportion of the LED elements assembled in a desired direction and the number of the LED elements assembled per unit area, thereby making it suitable for manufacturing various light-source products ranging from displays requiring high-resolution and high-brightness characteristics to lighting and the like.

### BRIEF DESCRIPTION OF THE DRAWINGS

FIGS. 1 and 2 are views of an LED electrode assembly according to one embodiment of the present invention wherein FIG. 1 is a plan view of the LED electrode assembly, and FIG. 2 is a cross-sectional view along line X-X′ in FIG. 1.

FIG. 3 is a perspective view and partial enlarged views of LED elements used in one embodiment of the present invention.

FIG. 4 is a schematic view of a manufacturing process for an LED electrode assembly according to one embodiment of the present invention.

FIGS. 5 and 6 are schematic views illustrating that the vertical alignment of LED elements on a first electrode surface during a manufacturing process for the LED electrode assembly varies with the surface tension (ST) and the vapor pressure (V) of the solvent in the LED element dispersion solution.

FIG. 7 shows SEM and TEM photographs of LED elements used in the LED electrode assembly according to one embodiment of the present invention.

FIG. 8 is a photograph of the first electrode surface provided with an organic coupling linker represented by Formula 1-1 used in the LED electrode assembly according to one embodiment of the present invention, wherein (b) is a SEM photograph, (c) is a contact angle photographing image, (d) is an FT-IR spectrum, and (e) and (f) are results of XPS spectrum analysis for Au 4f and S 2p, respectively.

FIG. 9 is an SEM photograph showing the alignment of LED elements on the upper portion of the LED electrode assembly according to one embodiment of the present invention.

FIG. 10 is a photograph of light emission from the LED electrode assembly according to various embodiments of the present invention, in which the size of the first electrode was varied.

FIG. 11 is a photograph of an LED electrode assembly according to Embodiment 5 of the present invention and a photograph of light emission when any subpixel is driven.

FIG. 12 is a graph showing the light emission characteristics of an LED electrode assembly implemented according to Embodiments 5 and 6, wherein (a) shows an electroluminescence (EL) spectrum at 300 K for each wavelength, (b) shows brightness with respect to applied driving voltage, (c) shows current density with respect to applied driving voltage, and (d) shows external quantum efficiency with respect to current density.

### DETAILED DESCRIPTION

Hereinafter, embodiments of the present invention will be described in detail so that those skilled in the art can easily implement them without undue experimentation. The present invention may be embodied in various forms and is not to be construed as limited to the embodiments set forth herein.

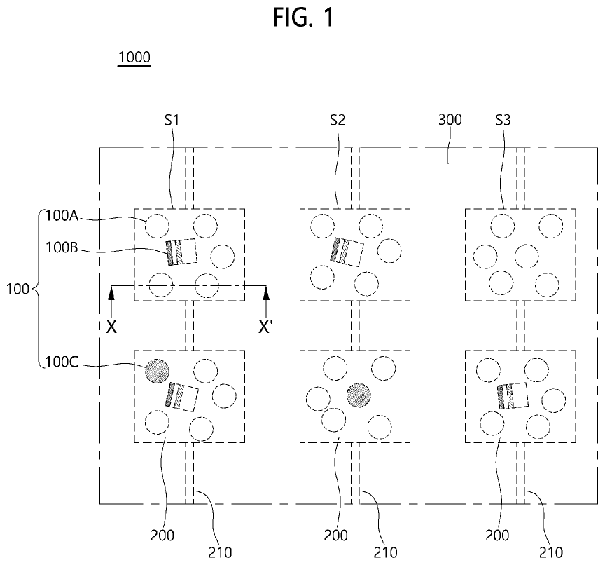

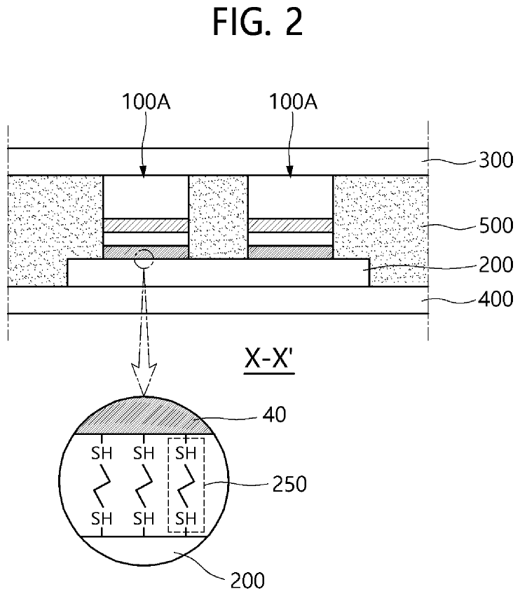

Referring to FIGS. 1 to 5, the LED electrode assembly 1000 according to an embodiment of the present invention includes a first electrode 200, a plurality of LED elements 100 disposed on the first electrode 200, and a second electrode 300 disposed to contact upper portions of the LED elements 100, and between the metal electrode layer 40 of first LED elements 100A, which are LED elements 100 mounted such that the metal electrode layer 40 faces the first electrode 200, and the first electrode 200, an organic coupling linker 250 having metal-binding groups at both ends, or a carbonized product thereof, is provided.

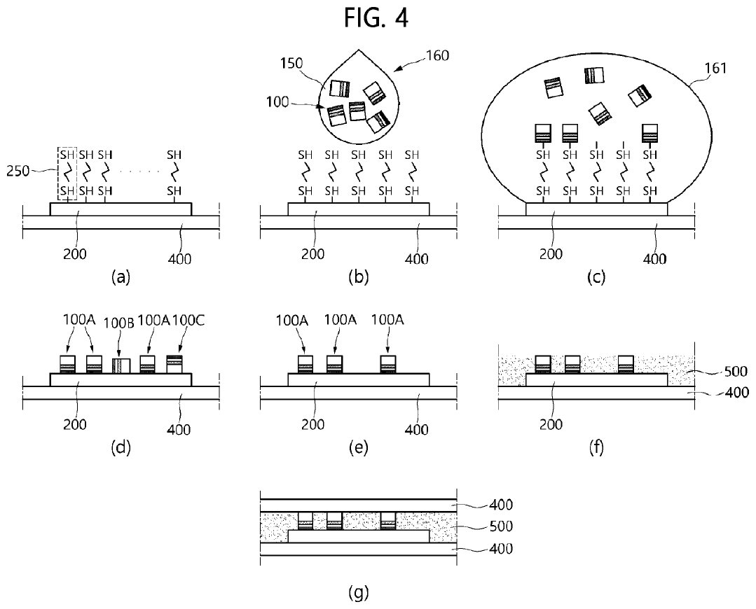

Regarding the manufacturing method for an LED electrode assembly 1000 includes: (1) a step preparing a first electrode 200 in which one end of an organic coupling linker 250 having least two terminal metal-binding groups at both ends, is bonded to the surface ((a) of FIG. 4); (2) a step of processing an LED element dispersion solution 160, which includes LED elements 100 and a solvent 150, onto the first electrode 200 on which the organic coupling linker 250 is disposed such that one side in the thickness direction where layers are stacked is a metal electrode layer 40 ((b) of FIG. 4); (3) a step of vertically assembling the LED elements 100 onto the first electrode 200 by forming a bond between the remaining metal-binding group in the organic coupling linker 250 bound to the first electrode 200 surface and the metal electrode layer 40 in the LED elements 100 ((c) and (d) of FIG. 4); and (4) a step of forming a second electrode 300 to be in electrical contact with the upper portion of the vertically assembled first LED element 100A ((g) of FIG. 4); wherein, in step (2), the LED element dispersion solution 160 may be configured so as to form droplets 161 having a contact angle of 10 to 72 degrees on the first electrode 200.

First, as step (1) according to the present invention, a first electrode 200, on whose surface one end of an organic coupling linker 250 having metal-binding groups at both ends is bonded, is prepared ((a) of FIG. 4).

The first electrode 200 is an electrode portion on which the LED element 100 is mounted and is a region where the organic coupling linker 250 is applied, and each may be set as a sub-pixel site (S₁, S₂, S₃) in the light source described below. In addition, when a plurality of first electrodes 200 are provided, connection electrodes 210 connecting all or some of the first electrodes 200 may be further formed, and this may be appropriately modified in consideration of driving control for the LED elements 100 assembled on the respective first electrodes 200, and the present invention is not particularly limited thereto.

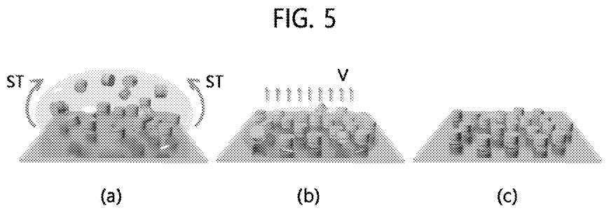

The first electrode 200 or a plurality of first electrodes 200 and connection electrodes 210 may be implemented in various known electrode patterns through a known method, and the present invention is not particularly limited thereto. For example, as shown in FIG. 5, a plurality of first electrodes 200 may be arranged to be spaced apart at predetermined intervals, and some first electrodes 200 may be set as one group, and connection electrodes 210 may be provided between the first electrodes 200 within the group.

In addition, the first electrode 200 may have an area of 1 μm² to 10 mm² and a thickness of 0.1 to 100 μm, but is not limited thereto.

In addition, the upper surface of the first electrode 200 may have a polygonal shape such as a square or a rectangle, a regular shape such as a circle or an ellipse, or an irregular shape, and the present invention is not particularly limited thereto.

In addition, the surface of the first electrode 200, which serves as a mounting surface for the LED element 100, may be made of a metal material known to bond with the metal-binding group at one end of the organic coupling linker 250 by covalent bonding, ionic bonding and/or electrostatic attraction, and may include one or more selected from gold, silver, and copper, or an alloy comprising any one or more thereof. For example, the first electrode 200 may be an electrode having a structure in which a gold (Au) layer is disposed on a chromium layer so as to be exposed on the surface thereof.

In addition, the first electrode 200 may be formed on a substrate 400, and for example, any one of a glass substrate, a quartz substrate, a sapphire substrate, a plastic substrate, or a flexible polymer film that can be bent may be used as the substrate 400. In another example, the substrate 400 may be transparent. However, it is not limited to the listed types, and any type of substrate capable of forming an electrode may be used.

In addition, the area of the substrate 400 is not limited and may be changed in consideration of the area of the first electrode 200 formed on the substrate 400. The thickness of the substrate 400 may be 100 μm to 1 mm, but is not limited thereto.

On the upper surface of the first electrode 200, an organic coupling linker 250 having metal-binding groups at least two ends is provided as a linker for vertically assembling a particular surface of the LED element 100, i.e., so that the metal electrode layer 40 contacts the upper surface of the first electrode 200, and the metal-binding groups of the organic coupling linker 250 function as anchors to fix the first electrode surface and the metal electrode layer 40 of the LED element 100 to each other via the organic coupling linker 250.

The organic coupling linker 250 includes a metal-binding group that serves as an anchor at its terminus for binding to a metal, and preferably the metal-binding group may include one or more of a thiol group and an amine group.

For example, an organic coupling linker provided with a metal-binding group, such as a thiol group, may be a compound represented by Formula 1.

### [Chemical Formula 1]

### HS-13 R—SH

Herein, R may be a straight or branched alkylene group having 1 to 10 carbon atoms or an arylene group having 6 to 12 carbon atoms, and more preferably, R may be a straight alkylene group having 2 to 5 carbon atoms or an arylene group having 6 to 12 carbon atoms. If R is an alkylene group having more than 10 carbon atoms or an arylene group having more than 12 carbon atoms, the vertical alignment of the LED element in step (3) described below may be deteriorated. In addition, if R is an alkylene group, it may be preferably a straight chain, thereby allowing the distance between organic coupling linkers 250 fixed on the first electrode surface to be arranged densely, which is advantageous for vertically assembling the LED element 100. Further, if R is an alkylene group, it may be preferably 2 to 5 carbon atoms, and if R is a methylene group or has more than 5 carbon atoms, the contact angle formed between the first electrode surface where the organic coupling linker is formed and droplets forming the LED element dispersion solution treated in step (2) described below becomes relatively small or large, so that sufficient time for LED alignment cannot be secured or, conversely, the alignment time may become longer, thus reducing the vertical alignment ratio. In addition, if R has more than 5 carbon atoms, the electron mobility between the first electrode and the LED element in the implemented LED electrode assembly may be reduced.

In addition, the organic coupling linker 250 may, in another example, be a secondary or tertiary amine compound having an amine as the metal-binding group. For example, the organic coupling linker 250 may include one or more selected from the group consisting of tris(2-aminoethyl)amine, ethylenediamine, diethylenetriamine, and triethylene tetramine.

In addition, the treatment of the organic coupling linker 250 may be performed by coating the first electrode 200 with a solution in which the organic coupling linker 250 is dissolved by a known method, and the present invention is not particularly limited thereto.

In addition, the solvent of the solution in which the organic coupling linker 250 is dissolved may be a known solvent capable of dissolving the same in consideration of the specific type of the organic coupling linker, and the present invention is not particularly limited thereto. For example, the solvent may be ethanol or water.

Meanwhile, in step (1), the organic coupling linker 250 may form a self-assembled monolayer (SAM) on the first electrode surface, and thus the organic coupling linker 250 is disposed on the first electrode 200 such that a metal-binding group that is not bonded within the organic coupling linker 250 is exposed toward an upper side of the first electrode 200, which is advantageous for increasing vertical alignment of the LED element 100 and for stably fixing the LED element on the first electrode 200, thereby preventing the LED element from falling over during post-processes such as drying or cleaning of the solvent in the LED element dispersion solution. The self-assembled monolayer formed by the organic coupling linker may be formed using known methods considering the specific type of the selected organic coupling linker and by appropriately selecting the solvent in which the organic coupling linker is dissolved, and the present invention is not particularly limited thereto. For example, an organic coupling linker containing a thiol group may form a self-assembled monolayer by immersing the first electrode in ethanol containing the organic coupling linker at a concentration of 0.8 to 10.0 mM at 35 to 45° C. for 20 to 30 hours. In addition, in the case of an organic coupling linker containing an amine group, a self-assembled monolayer may be formed by immersing the first electrode in an aqueous solution containing the organic coupling linker at a concentration of 0.8 to 10.0 mg/mL at 20 to 23° C. for 20 to 30 hours.

Next, as step (2) according to the present invention, a step of treating an LED element dispersion solution 160, which includes the LED element 100 which is a metal electrode layer 40, and the solvent 150, on a first electrode 200 having an organic coupling linker 250 disposed on a surface thereof is performed ((b) of FIG. 4).

The LED element dispersion solution 160 includes the LED element 100 and a solvent 150.

The LED element 100 may be a known LED element employed in the field of light sources and is not particularly limited thereto. For example, the LED element 100 includes a metal electrode layer 40 on one side in the thickness direction where layers comprising the element are stacked. The metal electrode layer 40 functions to align a particular surface of the LED element 100 by binding with a metal-binding group at one end of the organic coupling linker 250 that is fixed to the first electrode 200, thereby selectively standing the surface vertically on the first electrode 200. The metal electrode layer 40 may be formed of a known metal material capable of binding to the metal-binding group and may include one or more selected from gold, silver, copper, and alloys containing any one or more thereof. For example, the metal electrode layer 40 may be a metal electrode layer in which gold (Au) is stacked on Ti. In addition, the metal electrode layer 40 may have a thickness of 10 nm to 500 nm, but is not limited thereto.

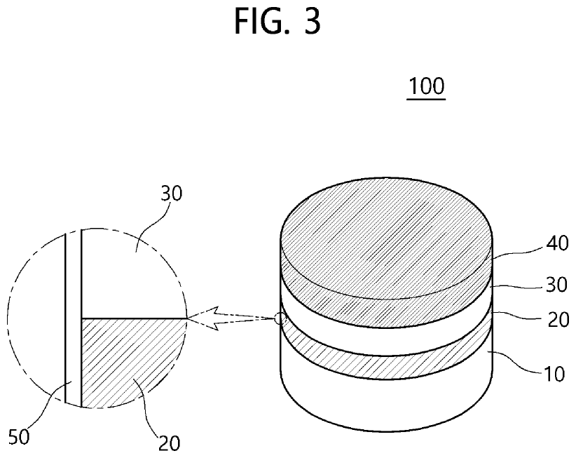

In addition, the shape of the LED element 100 may be a cylinder as shown in FIG. 3, but is not limited thereto, and may be a polyhedron such as a hexahedron, an octahedron, or a decahedron, as well as an irregular shape having star-shaped faces. In addition, the LED element 100 shown in FIG. 3 is illustrated as having a cross-sectional size perpendicular to the thickness direction that is uniform, but this is not limiting, and the cross-sectional size may vary depending on the thickness.

In addition, the LED element 100 may have a thickness of 0.5 to 3 μm, and an area of a surface perpendicular to the thickness direction may be 0.25 to 100 μm². Preferably, the LED element 100 may have a thickness-to-diameter ratio of one side perpendicular to the thickness direction in the range of 1:0.25 to 1:2.0, more preferably 1:0.25 to 1:1.6, thereby improving the vertical alignment ratio. If the thickness-to-diameter ratio of one side perpendicular to the thickness direction is less than 0.25, it is not easy to separate the LED element from the wafer, or due to the thin thickness of the LED element, the location where electrons and holes recombine may deviate from the photoactive layer, resulting in deterioration of appearance quality and luminous efficiency of the LED element and a risk of short circuit in the LED element. In addition, if the ratio of thickness to diameter of one side perpendicular to the thickness direction exceeds 2.0, there is a risk that the vertical alignment ratio of the LED elements may decrease. Herein, the one side perpendicular to the thickness direction refers to one side of the metal electrode layer 40, and the diameter refers to the length of the longest line segment crossing the metal electrode layer 40.

In addition, the LED element 100 may include, in addition to the metal electrode layer 40 provided on one side thereof, known layers constituting the LED element, for example, a first conductive semiconductor layer 10, a photoactive layer 20, and a second conductive semiconductor layer 30.

One of the first conductive semiconductor layer 10 and the second conductive semiconductor layer 30 may be an n-type semiconductor layer, and the other may be a p-type semiconductor layer, and the n-type semiconductor layer and the p-type semiconductor layer may be used without limitation as known semiconductor layers employed in light emitting diodes. For example, the n-type semiconductor layer and the p-type semiconductor layer may include group III-V semiconductors referred to as III-nitride materials, particularly binary, ternary, and quaternary alloys of gallium, aluminum, indium, and nitrogen.

For example, the first conductive semiconductor layer 10 may be an n-type semiconductor layer, and in this case, the n-type semiconductor layer may be selected from one or more semiconductor materials having a composition formula of InxAlyGal-x-yN (0≤x≤1, 0≤y≤1, 0≤x+y≤1), for example InAlGaN, GaN, AlGaN, InGaN, AlN, and InN, and a first conductive dopant (e.g., Si, Ge, Sn) may be doped therein. According to an embodiment of the present invention, the thickness of the first conductive semiconductor layer 10 may be 100 to 3000 nm, but is not limited thereto.

In addition, the second conductive semiconductor layer 30 may be a p-type semiconductor layer, and in this case, when the p-type semiconductor layer is selected from one or more of semiconductor materials having a composition formula of InxAlyGal-x-yN (0≤x≤1, 0≤y≤1, 0≤x+y≤1), such as InAlGaN, GaN, AlGaN, InGaN, AlN, and InN, a second conductive dopant (e.g., Mg) may be doped therein. According to an embodiment of the present invention, the thickness of the second conductive semiconductor layer 30 may be 50 nm to 150 nm, but is not limited thereto.

In addition, the photoactive layer 20 positioned between the first conductive semiconductor layer 10 and the second conductive semiconductor layer 30 may be formed of a single or multiple quantum well structure. The photoactive layer 20 may be used without limitation when it is a photoactive layer included in a conventional LED element used for lighting, display, etc. A clad layer (not shown) doped with a conductivity dopant may be formed above and/or below the photoactive layer 20, and the clad layer doped with the conductivity dopant may be implemented by an AlGaN layer or an InAlGaN layer. Other materials such as AlGaN, AlInGaN, etc., may also be used as the photoactive layer 20. In the photoactive layer 20, when an electric field is applied to the elements, electrons and holes which move from the conductive semiconductor layers to the photoactive layer, located above and below the photoactive layer recombine in the photoactive layer to form electron-hole pairs, thereby emitting light. According to one embodiment of the present invention, the thickness of the photoactive layer 20 may be 50 nm to 200 nm, but is not limited thereto.

In addition, the LED element 100 may further include a protective film 50 surrounding the element side surface when the side surface parallel to the stacking direction is referred to as the element side surface. The protective film 50 serves to protect surfaces of the first conductive semiconductor layer 10, the photoactive layer 20 and the second conductive semiconductor layer 30. For example, the protective film 50 may include one or more selected from silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN) and gallium nitride (GaN). The thickness of the protective film 50 may be in a range of 5 nm to 100 nm, preferably 30 nm to 100 nm.

In addition, the first conductive semiconductor layer 10, the photoactive layer 20, and the second conductive semiconductor layer 30 that may be provided in the LED element 100 described above may be included as minimum constituent elements of the LED element, and it is noted that other phosphor layers, quantum dot layers, other active layers, semiconductor layers, hole blocking layers, and/or electrode layers may further be included above and/or below each of these layers.

Meanwhile, the above-described LED element may be manufactured by known methods, and for example, KR Patent Publication No. 2012-0122159 by the inventor of the present invention is incorporated herein by reference. In addition, KR Patent Publication No. 2022-0096608 on a method of separating etched LED structures of various shapes and sizes from a wafer is incorporated herein by reference. In addition, the LED elements may incorporate herein by reference Korean Patent Application No. 10-2024-0165627, which discloses a manufacturing method for LED elements in which surface defects generated during an etching process are recoverable after dry etching, and thus a detailed description thereof is omitted.

Next, the solvent 150 provided in the LED element dispersion solution 160 will be described. The solvent 150 serves as a moving medium for dispersing the plurality of LED elements 100 and moving them to an upper surface of the first electrode 200. In addition, the solvent 150 has a function of securing space necessary for direction change such that the metal electrode layer 40 of the LED element 100 faces the upper surface of the first electrode 200 while the LED element 100 is randomly introduced without being fixed in a plane direction and then moves up to the upper surface of the first electrode 200 by settling down in the solvent, and to this end, the LED element dispersion solution 160 may be configured with the solvent 150 so as to form droplets 161 having a contact angle of 10 to 72 degrees on the first electrode 200.

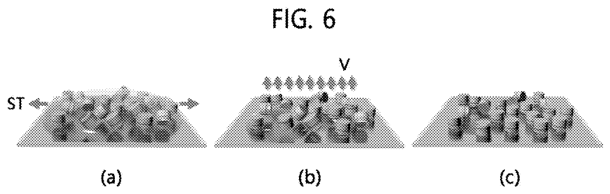

Referring to FIGS. 5 and 6, droplets 161 formed by the contact of the LED element dispersion solution 160 with an upper surface of the first electrode 200 have a suitable contact angle and surface tension (ST) that provide space for converting the orientation of a specific side of the LED element 100, namely the metal electrode layer 40, so that it faces the upper surface of the first electrode 200, and as shown in FIG. 6, when the contact angle of the LED element dispersion solution 160 on the upper surface of the first electrode 200 is small, the LED element dispersion solution 160 spreads out on the upper surface of the first electrode 200, thereby reducing the distance between the droplet 161 of the LED element dispersion solution 160 and the first electrode 200, and thus the space for the metal electrode layer 40 of the LED element 100 to reorient toward the upper surface of the first electrode 200 is not secured, making it difficult to significantly improve the ratio at which the metal electrode layer 40 is vertically aligned on the first electrode 200. In this regard, the LED element dispersion solution 160 may have a contact angle of 10° to 72° with the first electrode surface on which the organic coupling linker is disposed, or alternatively 15° to 72°. When the contact angle of the LED element dispersion solution 160 with respect to the first electrode is less than 10°, the droplet 161 of the LED element dispersion solution 160 spreads more, thereby decreasing the height of the droplet 161 and reducing the space required for vertical alignment, which can greatly decrease the vertical alignment ratio of the LED elements. In addition, if the contact angle between the LED element dispersion solution 160 and the first electrode exceeds 72°, the implementation time of the LED electrode assembly is extended, and there is a concern that the increase in the vertical alignment ratio is insignificant or the direction of the LED elements is rather frequently changed, so that the vertical alignment ratio rather decreases. Herein, the contact angle refers to the contact angle measured at room temperature, e.g., 20° C., and not to a value measured at the process temperature at which step (3), which is the reference temperature for the surface tension and vapor pressure of the solvent, is performed.

In addition, preferably, the solvent in the LED element dispersion solution 160 may have a surface tension of 26 mN/m or more and, in another example, 76 mN/m or less, which is advantageous for ensuring that the droplet 161 formed by the LED element dispersion solution 160 secures sufficient space and time to improve vertical alignment of the LED elements. If the surface tension of the solvent in the LED element dispersion solution 160 is less than 26 mN/m, the spreadability of the LED element dispersion solution 160 increases, and thus the vertical alignment ratio of the LED elements may significantly decrease. In addition, if the surface tension of the LED element dispersion solution 160 on the first electrode exceeds 76 mN/m, the time required to implement the LED electrode assembly may be extended, and solvent molecules evaporating during a process of drying the solvent may act as an external force that causes the vertically aligned LED elements to topple. Herein, the surface tension of the solvent refers to the surface tension at the temperature condition at which step (3) described below is performed.

In addition, the LED element dispersion solution 160 may have a vapor pressure of 10 mmHg or less, more preferably 6 mmHg or less, still more preferably 2 mmHg or less, and even more preferably 1 mmHg or less so that droplets 161 formed on the first electrode 200 are provided with sufficient space for direction change of the LED elements, while the formed space is maintained during time required to vertically align the LED elements 100 on the first electrode 200. If the vapor pressure of the solvent exceeds 10 mmHg, although the droplets formed on the upper surface of the first electrode 200 form sufficient space immediately after the introduction of the LED element dispersion solution 160, as shown in FIG. 6, it may be difficult to secure necessary space and time for direction change of the LED elements due to rapid evaporation of the solvent, and evaporated solvent molecules may act as an external force which causes vertical alignment of the LED elements to collapse, thereby making it difficult to achieve high vertical alignment ratio. The vapor pressure of the solvent means a vapor pressure at temperature condition where step (3) described later is performed.

The solvent 150 is not particularly limited to the kind of solvent, as long as the LED element dispersion solution 160 forms a contact angle according to the present invention with the upper surface of the first electrode coated with the organic coupling linker 250 and the solvent in the droplets 161 has preferred levels of surface tension and vapor pressure under the temperature conditions at which step (3) described below is performed, and mixed solvents may also be used if they satisfy the above-described physical property conditions. For example, the solvent 150 may include one or more solvents selected from water, ethanol, gamma-butyrolactone (GBL), and propylene glycol methyl ether acetate (PGMEA).

In addition, the LED element dispersion solution 160 may contain the LED elements 100 at a weight % of 0.1 to 10 wt %, which is advantageous for improving the number of LED elements vertically aligned in a desired direction per unit area of the first electrode in the implemented LED electrode assembly. If the LED elements 100 are less than 0.1 wt %, the implemented LED electrode assembly may have difficulty exhibiting sufficient brightness, and if they exceed 10 wt %, it may be difficult to secure space in the LED element dispersion solution droplet for switching the directions of the LED elements, thereby making it difficult to achieve a vertical alignment ratio at the desired level.

In addition, the LED element dispersion solution 160 may preferably be deposited to form one droplet on each first electrode, thereby advantageously increasing a ratio of vertically aligned LED elements in a desired electrode area. In addition, one droplet applied to each first electrode may be 2 to 10 l, but is not limited thereto.

Next, as step (3), a step of vertically assembling the LED element 100 on the first electrode 200 ((c) of FIG. 4) is performed by forming a bond is formed between the remaining metal-binding group in the organic coupling linker 250 bonded to the first electrode 200 and the metal electrode layer 40 in the LED element 100, thereby

The space secured by the droplet 161 formed on the upper surface of the first electrode 200 by the LED element dispersion solution allows the LED element 100 to change direction in the solvent 150 such that the metal electrode layer 40 faces the upper surface of the first electrode 200, and thus a contact angle at an appropriate level and, in addition, the surface tension of the solvent may act as an external force required for changing the direction of the LED element 100 within the solvent 150 together with one or more types of binding forces between the metal-binding group of the organic coupling linker 250 provided on the first electrode 200 surface and the metal electrode layer 40 of the LED element, including covalent bonds, ionic bonds, and electrostatic attraction, thereby implementing an LED electrode assembly having a high vertical alignment ratio. The type of binding between the organic coupling linker 250 on the upper surface of the first electrode 200 and the metal electrode layer 40 of the LED element varies depending on the specific type of organic coupling linker 250, but the present invention is not limited thereto.

In addition, step (3) may be performed at a temperature of more than 0° C. to 80° C. for 10 minutes to 24 hours, but is not limited thereto.

step (3), in addition to the first LED elements 100A vertically aligned so that the metal electrode layer 40 contacts the upper surface of the first electrode 200, second LED elements 100B mounted such that a side surface of the element contacts the upper surface of the first electrode 200 and third LED elements 100C mounted such that a surface opposite to the side on which the metal electrode layer 40 is formed contacts the upper surface of the first electrode 200 may also be included; and when the surface tension and contact angle parameters between the surface of the first electrode 200 provided with the above-described organic coupling linker 250 and the LED element dispersion solution 160 satisfy predetermined conditions, it is advantageous for substantially improving a ratio of the first LED elements 100A among the LED elements 100 positioned on the first electrode 200; for example, after performing step (3), the ratio of the first LED elements 100A may be 40% or more, preferably 50% or more, more preferably 60% or more, and even more preferably 80% or more, thereby enabling a substantial portion of the input LED elements to be aligned in an operable state.

According to an embodiment of the present invention, a cleaning step may be further included to clean the surface of the first electrode 200 so as to remove misaligned LED elements on the surface of the first electrode 200, that is, the second LED elements 100B and the third LED elements 100C between step (3) and a subsequent step (4) ((e) of FIG. 4).

Removing the misaligned LED elements, that is, second LED elements 100B and third LED elements 100C, through the cleaning step prevents electrical short circuits that may occur during driving of the LED electrode assembly 1000 and also enables recovery of the misaligned LED elements, thereby reducing costs. The cleaning solution used for the cleaning may be any solvent that does not weaken a bond between the metal-binding groups in the organic coupling linker interposed between the metal electrode layer 40 of the first LED element 100A and the first electrode 200, and for example, water, isopropyl alcohol, and toluene may be used.

In addition, according to an embodiment of the present invention, between step (3) and step (4), particularly when a cleaning step is performed as described above, a heat treatment step may be further performed at 200° C. to 600° C. for 3 to 10 minutes in order to increase the coupling force between the first LED element 100A and the first electrode 200 before performing the cleaning step ((d) of FIG. 4). The heat treatment step increases the coupling force between the first LED element 100A and the first electrode 200, thereby preventing the first LED element 100A from toppling due to external forces caused by flow of the cleaning solution in a subsequent cleaning step and thus facilitating subsequent processes without changing the ratio of the first LED elements 100A. If the heat treatment temperature and/or time are not met, it may be difficult to achieve or maintain sufficient coupling force, which may result in a decrease in the ratio of the first LED elements during various post-processes.

Meanwhile, the organic coupling linker 250 may be partially or completely carbonized in the final LED electrode assembly due to the heat treatment step, and carbon and nitrogen- and/or sulfur-containing carbides detected between the LED element and the first electrode in the LED electrode assembly may serve as indirect evidence of the presence of the organic coupling linker containing metal-binding groups.

Next, as step (4), a step of forming a second electrode 300 to be in electrical contact with an upper portion of the vertically assembled first LED element 100A.

The second electrode 300 is an electrode for driving the first LED element 100A and is preferably formed to be in electrical contact with the first LED element 100A, the second electrode 300 may have various electrode patterns, and the present invention is not particularly limited thereto. For example, the second electrode 300 may be integrally formed to cover areas corresponding to a plurality of first electrodes 200.

The second electrode 300 is not limited in the material of the electrode used for driving an LED employed as a light source, and may be, for example, aluminum, chromium, gold, silver, copper, graphene, or an alloy thereof. Alternatively, the second electrode 300 may be a transparent electrode such as ITO, which is known in the art, thereby improving brightness by increasing total transmittance of light. The thickness of the second electrode 300 may be 0.1 to 100 μm, but is not limited thereto.

In addition, step (4) may further include forming a passivation layer 500 on the first LED element 100A to fix and insulate the first LED element 100A before formation of the second electrode 300 and to provide a surface for forming the second electrode 300. The passivation layer 500 may be formed using any passivation material commonly used in electrical and electronic components without limitation. For example, the passivation layer 500 may be deposited by a PECVD process using a passivation material such as SiO₂ or SiNₓ, deposited by an MOCVD process using a passivation material such as AlN or GaN, or deposited by an ALD process using a passivation material such as Al₂O₃, HfO₂, or ZrO₂. Meanwhile, the passivation layer 500 should be formed so as not to cover the upper surface of the first LED element 100A, and to this end, the passivation layer may be formed by deposition to a thickness that does not cover the upper surface, or it may be deposited so as to cover the upper surface and then a dry etching may be performed so that the upper surface of the LED elements is exposed, and the present invention is not particularly limited in this respect.

The LED electrode assembly 1000 implemented by the above-described manufacturing method can achieve a ratio of first LED elements 100A of 80% or more, more preferably 95% or more, after the cleaning step, and can be mounted such that the number of first LED elements 100A mounted per unit area of 10,000 μm² is 40 or more, more preferably 60 or more, still more preferably 80 or more, and even more preferably 90 or more, thereby implementing an LED electrode assembly 1000 having sufficient brightness and high resolution.

In addition, the position where each first electrode 200 is disposed in an implemented LED electrode assembly may be a sub-pixel site (S₁, S₂, S₃) of the LED electrode assembly, so that one LED electrode assembly can constitute one or more pixels to display various colors of high resolution images at high brightness.

In addition, the light source may be used without limitation in various electric and electronic components or devices using LEDs such as lighting, medical devices, cosmetic devices, etc. other than displays.

The following embodiments are provided to further illustrate the present invention, but should not be construed as limiting the scope of the present invention.

### Example 1

First, LED elements were prepared as follows. Specifically, a conventional LED wafer (Epistar) in which an undoped n-type III-nitride semiconductor layer, an n-type III-nitride semiconductor layer doped with Si (thickness: 4 μm), a photoactive layer (thickness: 0.15 μm), and a p-type III-nitride semiconductor layer (thickness: 0.05 μm) were sequentially stacked on the substrate was prepared. On the prepared LED wafer, an ITO electrode layer (thickness: 150 nm), a first mask layer of SiO₂ (thickness: 0.9 μm), and a second mask layer of Al (thickness: 150 nm) were sequentially deposited, and then a SOG resin layer having circular pattern with a diameter of 1000 nm was transferred onto the second mask layer using a nanoimprint equipment. Then, the SOG resin layer was cured by RIE, and residual resin portions of the resin layer were etched through RIE to form a resin pattern layer. Subsequently, the second mask layer was etched using ICP along the pattern, and the first mask layer was etched using RIE. Thereafter, the ITO layer, the p-type III-nitride semiconductor layer, and the photoactive layer were etched using ICP, and then the doped n-type III-nitride semiconductor layer was etched to a thickness of 1.1 μm, and then the mask pattern layer was removed through KOH wet etching to manufacture an LED wafer including a plurality of LED structures. Then, a protective film of SiO₂ was deposited on the LED wafer including the plurality of LED structures (deposition thickness is 50 nm based on the side surface of the LED structure), and thereafter the protective film material formed between the plurality of LED structures was removed by RIE to expose the upper surface of the doped n-type III-nitride semiconductor layer between the LED structures.

Then, the LED wafer with the protective film formed thereon was immersed in a 0.3 M aqueous oxalic acid electrolyte and connected to the anode terminal of a power source, and a cathode terminal was connected to a platinum electrode immersed in the electrolyte, followed by applying a voltage of 5 V for 5 minutes to form multiple pores extending in the thickness direction from the surface of the doped n-type III-nitride semiconductor layer between the LED structures. Thereafter, the protective film covering the ITO was removed by CHF₃-based RIE, and Au was deposited (Au thickness is 10 nm) on the ITO electrode layer to form a metal electrode layer in which ITO and Au are stacked. Then, the LED wafer was immersed in a bubble-forming solution of 100% gamma-butyrolactone and ultrasonic irradiation was applied at 160 W and 40 kHz for 10 minutes to collapse the pores formed in the doped n-type III-nitride semiconductor layer using the generated bubbles, thereby producing a plurality of LED elements (diameter is 1 μm, thickness is 1.1 μm), and the produced LED elements were collected and purified by centrifugation in ethanol.

In order to prepare a plurality of first electrodes, as shown in FIG. 1, chromium and gold layers having thicknesses of 10 nm and 200 nm, respectively, were deposited on a quartz base substrate having a thickness of 500 μm and an area of 25×25 mm² to form first electrode patterns each having an area of 900 mm², thereby preparing first electrodes comprising stacked chromium and gold layers. Thereafter, the first electrodes were treated in the dark at 40° C. for 24 hours with a 1 mM ethanol solution of the organic coupling linker represented by Formula 1-1, and then washed with ethanol to prepare first electrodes treated with the organic coupling linker.

### [Chemical Formula 1-1]

HS—R—SH, wherein R is an ethylene group.

The purified LED elements were mixed with gamma-butyrolactone solvent (contact angle of a droplet formed by the first electrode surface treated with Formula 1-1: 17° at 20° C.; vapor pressure: 0.45 mmHg at 20° C.; surface tension: 44.6 mN/m) at a concentration of 0.25 wt % to prepare an LED element dispersion solution, which was then applied onto the prepared first electrode in a chamber set to 20° C. at a volume of 2 μL, and the LED elements were vertically aligned on the first electrode for 12 hours.

After heat treatment at 300° C. for 5 minutes, the misaligned LED elements were removed from the first electrode by washing with water several times. Then, an insulating layer was patterned on the first electrode where the first LED elements are vertically aligned using SU-8 negative photoresist, and the n-GaN layer of the LED element was exposed by CHF₃-based RIE. Finally, a second electrode was formed by sputtering IZO to a thickness of 300 nm on the first LED element to fabricate an LED electrode assembly.

### <Experimental Example 1>

The following evaluations were performed on the LED element prepared in Example 1, the first electrode surface treated with an organic coupling linker, and the LED electrode assembly manufactured according to Example 1.

### 1. Observation of the LED Element

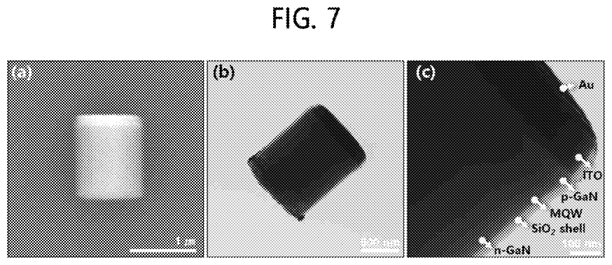

SEM photographs of the fabricated LED elements are shown in FIG. 7.

As shown in FIG. 7, it is found that a metal electrode layer including an Au layer is formed on one side of the LED element.

### 2. Determination of Whether the Organic Coupling Linker is Fixed on the First Electrode Surface or not.

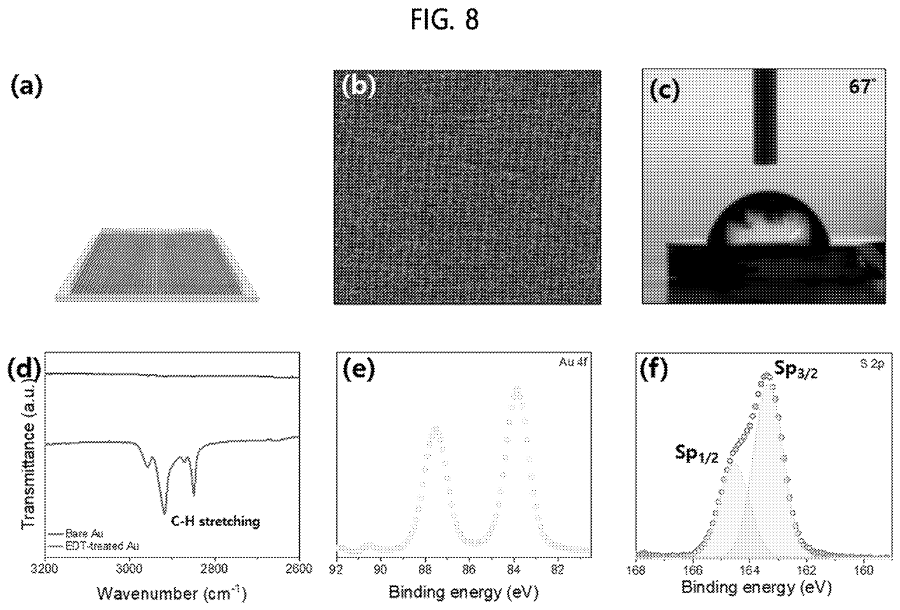

The organic coupling linker represented by Formula 1-1 was applied to the first electrode and measured by an atomic force microscope (AFM) in non-contact mode, and the results are shown in (b) of FIG. 8.

In addition, after treatment with the organic coupling linker, a drop of water having a predetermined volume was formed on the first electrode surface using a contact angle meter at room temperature (20° C.), the first electrode surface treated with the organic coupling linker was brought into contact with the formed drop to produce a contact angle, which was measured using the program of the contact angle meter, and the results are shown in (c) of FIG. 8.

As shown in (b) and (c) of FIG. 8, the organic coupling linker represented by Formula 1-1 is fixed on the first electrode surface, and specifically, organic coupling linker molecules form a self-assembled monolayer on the Au layer of the first electrode surface, so that the organic coupling linkers are uniformly vertically aligned. In addition, as can be seen from (c) of FIG. 8, the contact angle between the first electrode having the organic coupling linker formed thereon and water is 67°, which differs from the contact angle (less than 10°) of the first electrode surface in the UV—O₃-treated state prior to treatment with the organic coupling linker, indicating that the physical and chemical properties of the first electrode surface have been modified by the organic coupling linker represented by Chemical Formula 1.

In addition, FT-IR and XPS analyses were performed on the first electrode treated with the organic coupling linker represented by Chemical Formula 1-1, and the results are shown in (d) to (f) of FIG. 8. For the FT-IR analysis, a substrate not treated with the compound represented by Formula 1-1 and a substrate treated with the compound represented by Formula 1-1 at a concentration of 1 mM were prepared, and FT-IR spectra of both substrates were measured in attenuated total reflectance (ATR) mode using an FT-IR spectrometer, thereby obtaining the graph presented in FIG. (d) of 8.

As can be seen in (d) to (f) of FIG. 8,

It can be confirmed from the C—H stretching peak at 2800 to 3000 cm⁻¹ in the FT-IR spectrum that the organic coupling linker represented by Chemical Formula 1 has been deposited. In addition, analysis of the Au 4f and S 2p peaks in the XPS spectrum confirms that the thiol metal-binding group of the organic coupling linker molecule represented by Formula 1-1 is bonded to the Au layer of the first electrode surface, and thus indirectly confirms successful self-assembly of the organic coupling linker molecules represented by Formula 1-1 on the Au layer surface and indirectly confirming the formation of a monolayer of the organic coupling linker molecules.

### 3. Observation of the Vertical Alignment Direction of the LED Elements in the LED Electrode Assembly.

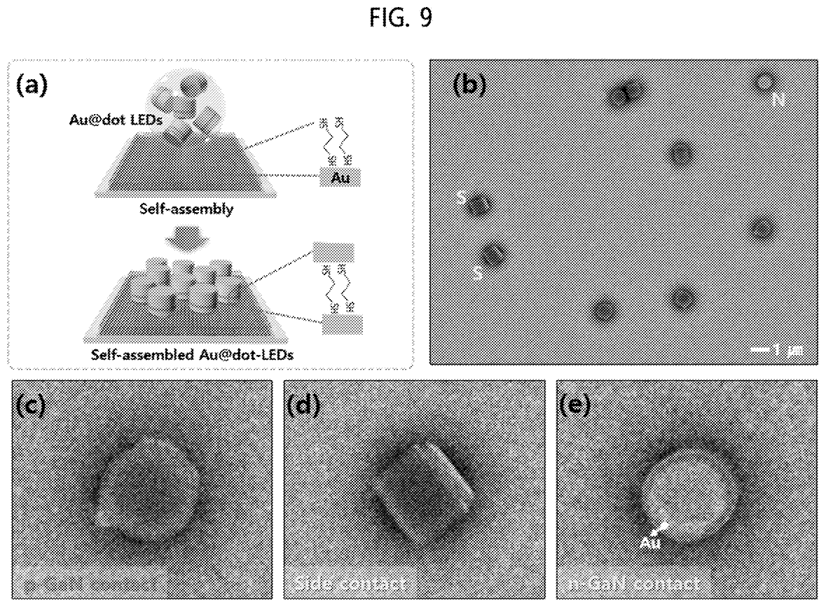

After vertically aligning the LED elements, an SEM photograph was taken of the first electrode on which the LED elements were mounted before washing to observe the vertical alignment direction of the LED elements, and the SEM photograph is shown in FIG. 9.

As shown in FIG. 9,

on the first electrode surface, a large proportion of the first LED elements ((c) of FIG. 9), in which an Au layer contacts the first electrode surface to form a p-contact, are present, while second LED elements ((d) of FIG. 9), in which side surfaces of the LED elements are contacted, and third LED elements ((e) of FIG. 9), in which an n-GaN contact is formed, are also observed.

### Examples 2 to 4

An LED electrode assembly was manufactured in the same manner as Example 1, except that the first electrode was changed such that square subpixels were formed on a 1×1 mm² substrate, each first electrode had a side length of 10 μm, 20 μm, and 40 μm, respectively, and the spacings between the first electrodes were 85 μm, 55 μm, and 35 μm.

### <Experimental Example 2>

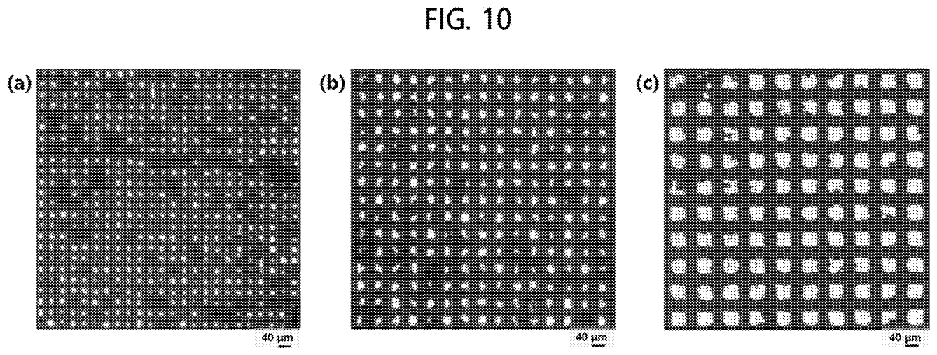

Photographs of the optical microscope images of the LED electrode assemblies emitting light by applying a driving power to the LED electrode assemblies according to Examples 2 to 4 are shown in (a) (Example 2), (b) (Example 3), and (c) (Example 4) of FIG. 10.

As shown in (a) to (c) of FIG. 10, a plurality of subpixels in each LED electrode assembly are emitting light.

In addition, it can be confirmed that the LED electrode assembly according to Embodiment 2 achieves a resolution of about 726 PPI for blue monochromatic color, which is much higher than the resolution of about 400 PPI of commercialized smart watches.

### Example 5

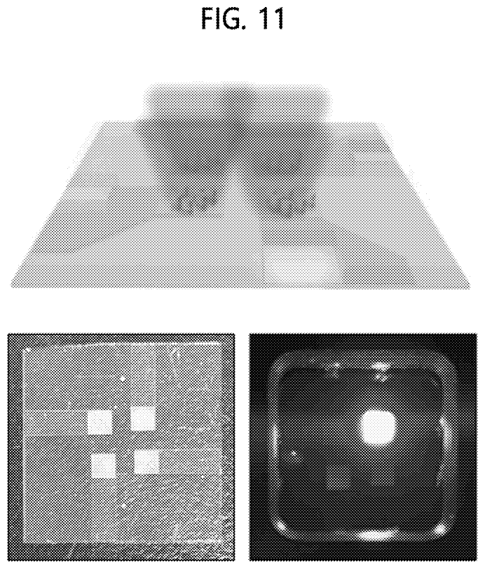

An LED electrode assembly shown in FIG. 11 was manufactured in the same manner as Example 1, except that the size of each first electrode was changed to 3×3 mm² and the first electrodes were redesigned so that four first electrodes could independently driven.

### Example 6

An LED electrode assembly was manufactured in the same manner as Example 5, except that the solvent in the LED element dispersion solution was changed to ethanol (contact angle of less than 3° with the first electrode surface treated with Formula 1-1, vapor pressure of 44.63 mmHg at 20° C., and surface tension of 22.27 mN/m).

### <Experimental Example 3>

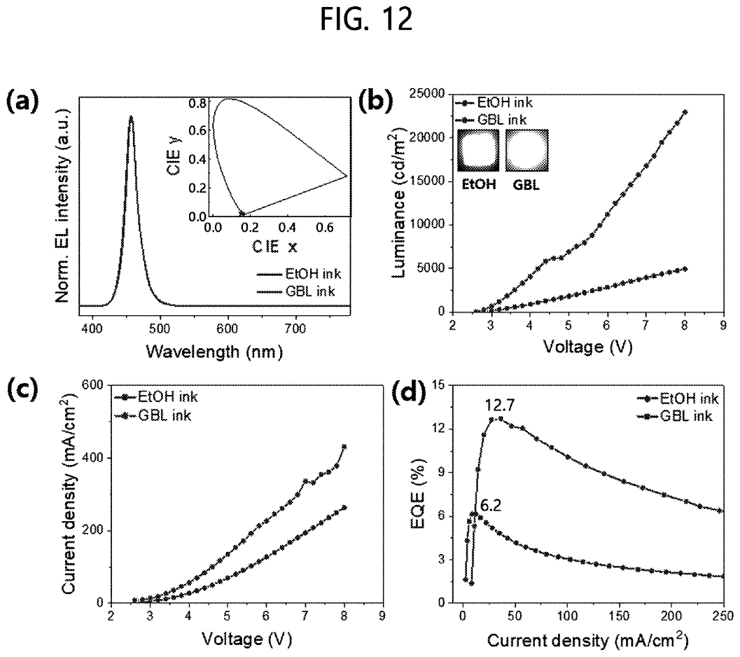

After applying a driving voltage to the LED electrode assembly according to Examples 5 and 6, light emission characteristics of any one of four subpixels were evaluated using a Keithley 2001 multimeter (Keithley Instruments Inc.) and a CS-2000 spectroradiometer (Konica-Minolta), and the results are shown in FIG. 12.

Herein, (a) of FIG. 12 is an electroluminescence (EL) spectrum at 300 K for each wavelength, (b) is a graph of luminance according to the applied driving voltage, (c) is a graph of current density according to the applied driving voltage, and (d) is a graph of external quantum efficiency according to current density.

As shown in FIG. 12,

it can be confirmed that one subpixel in the LED electrode assembly according to Example 5 achieved a maximum EQE of 120.7% at 3.4 V and a brightness of 22,950 cd/m−² at 8.0 V. In contrast, one subpixel in the LED electrode assembly according to Example 6 achieved a maximum EQE of 6.2% at 3.4 V and a brightness of 4,942 cd/m−² at 8.0 V, and Example 5, compared with Example 6, exhibits an external quantum efficiency at least twice that of Example 6 and a brightness improved by at least 4.6 times.

### Examples 7 to 9

An LED electrode assembly was manufactured in the same manner as Embodiment 1, except that the type of solvent in the LED element dispersion solution and the alignment temperature were changed, respectively, to water (alignment temperature: 10° C.), water (alignment temperature: 5° C.), water (alignment temperature: 20° C.), and ethanol (alignment temperature: 20° C.).

### Example 10

An LED electrode assembly was manufactured in the same manner as in Embodiment 1, except that tris(2-aminoethyl)amine was used as the organic coupling linker, the solvent used for dissolving the same, was changed to water to form a self-assembled monolayer on the first electrode, the solvent in the LED element dispersion solution was changed to water, and the alignment temperature was set to 5° C.

### Comparative Examples 1 and 2

The LED electrode assembly was manufactured in the same manner as Embodiment 1, except that the solvent type and the alignment temperature in the LED element dispersion solution were changed to ethanol (alignment temperature: 20° C.) and acetone (alignment temperature: 20° C.), respectively.

### <Experimental Example 4>

The physical properties of the LED electrode assemblies according to 1 and 7 to 10 and Comparative Example 1 were evaluated as follows, and the results are shown in Table 1.

### 1. Measurement of the Contact Angle Between the Solvent in the LED Element Dispersion Solution and the First Electrode

The evaluation was performed in the same manner as Experimental Example 1.

### 2. Surface Tension and Vapor Pressure of Solvent in the LED Element Dispersion Solution

The surface tension and vapor pressure of the solvents were determined with reference to the product data sheets of the manufacturers from which the solvents were purchased and the website https://pubchem.ncbi.nlm.nih.gov.

### 3. Observation of the Vertical Alignment Direction of the LED Elements in the LED Electrode Assembly

After vertically aligning the LED elements, a SEM photograph was taken of the first electrode on which the LED elements were mounted before cleaning to observe the vertical alignment direction of the LED elements, and the numbers of p-contacts (Au metal electrode layer contacts), n-contacts, and side contacts were counted to calculate a vertical alignment ratio, which is the ratio of the number of p-contacted LED elements on the first electrode to the total number of LED elements disposed on the first electrode.

4. Evaluation of the Number and Ratio of p-Contact Vertically Aligned Elements Per Unit Area of the First Electrode of the LED Electrode Assembly

After vertically aligning the LED elements and washing with water, a SEM photograph was taken of the first electrode on which the LED elements were mounted to observe the vertical alignment direction of the LED elements, and the numbers of p-contacts (Au metal electrode layer contacts), n-contacts, and side contacts were counted to calculate a vertical alignment ratio, which is a ratio of the number of p-contacted LED elements on the first electrode to the total number of LED elements disposed on the first electrode. In addition, the number of p-contact vertically aligned elements per unit area of 10,000 μm 2 of the first electrode was calculated.

TABLE 1

| | | Example | Example | Example | Example | Example | Comparative | Comparative |
|---|---|---|---|---|---|---|---|---|
| | | 1 | 7 | 8 | 9 | 10 | Example 1 | Example 2 |
| Organic | | Chemical | Chemical | Chemical | Chemical | Tris(2- | Chemical | Chemical |
| bonding linker | | Formula | Formula | Formula | Formula | aminoethyl) | Formula | Formula |
| | | 1-1 | 1-1 | 1-1 | 1-1 | amine | 1-1 | 1-1 |
| Temperature | | 20 | 5 | 10 | 20 | 5 | 20 | 20 |
| during LED | | | | | | | | |
| element | | | | | | | | |
| alignment (° C.) | | | | | | | | |
| Solvent | Type | gamma- | Water | Water | Water | Water | Ethanol | Acetone |
| in LED | | butyrolactone | | | | | | |
| element | Contact | 17 | 67 | 67 | 67 | 67 | <3 | <3 |
| dispersion | angle | | | | | | | |
| solution | with first | | | | | | | |
| | electrode | | | | | | | |
| | surface (°) | | | | | | | |
| | Vapor | 0.45 | 6.55 | 9.21 | 17.54 | 6.55 | 44.63 | 230 |
| | pressure | | | | | | | |
| | (mmHg) | | | | | | | |
| | (temperature | | | | | | | |
| | when @ | | | | | | | |
| | alignment) | | | | | | | |
| | Surface | 44.6 | 74.94 | 74.2 | 71.97 | 74.94 | 22.27 | 23.7 |
| | tension | | | | | | | |
| | (mN/m) | | | | | | | |
| | (temperature | | | | | | | |
| | when @ | | | | | | | |
| | alignment) | | | | | | | |
| LED | Vertical | 83.0 | 51.9 | 42.6 | 5.2 | 44.2 | 17.2 | 9.8 |
| electrode | alignment | | | | | | | |
| assembly | ratio (%) | | | | | | | |
| | (before | | | | | | | |
| | cleaning) | | | | | | | |
| | Vertical | 98.0 | 84.6 | 82.4 | 34.7 | 81.3 | 68.9 | 59.1 |
| | alignment | | | | | | | |
| | ratio (%) | | | | | | | |
| | (after | | | | | | | |
| | cleaning) | | | | | | | |
| | Number | 101.2 | 68.1 | 67.2 | 12.1 | 40.2 | 26.7 | 10.5 |
| | of p- | | | | | | | |
| | contacted | | | | | | | |
| | vertically | | | | | | | |
| | aligned | | | | | | | |
| | elements per | | | | | | | |
| | 10,000 μm² | | | | | | | |
| | (after | | | | | | | |
| | cleaning) | | | | | | | |

As shown in Table 1,

the LED electrode assembly manufactured according to Examples 1 and 7-8 and Example 10 has a vertical alignment ratio and the ratio of vertically aligned LED elements per unit electrode area higher than those of Comparative Examples 1 and 2 because it satisfies the contact angle between the first electrode surface treated with an organic coupling linker and the LED element dispersion solution, the surface tension and vapor pressure of the solvent in the LED element dispersion solution at the temperature where the LED alignment process is performed.

Although the present invention has been described with reference to specific embodiments, the spirit of the present invention is not limited to the embodiments set forth herein, and those skilled in the art will readily be able to propose other embodiments by adding, modifying, deleting, or substituting components within the scope of the same inventive concept, which are also intended to fall within the spirit and scope of the present invention.

1. A manufacturing method for an LED electrode assembly comprising the steps of:
(1) preparing a first electrode on which one end of an organic coupling linker having metal-binding groups at both ends is bound to a surface;
(2) treating, on the first electrode on which the organic coupling linker is disposed, an LED element dispersion solution comprising a solvent and LED elements, wherein each of LED elements has a metal electrode layer on one side and a structure in which layers are stacked in a thickness direction;
(3) forming a bond between the remaining metal-binding group of the organic coupling linker and the metal electrode layer of the LED element to vertically assemble the LED element on the first electrode; and
(4) forming a second electrode to be in electrical contact with an upper portion of the vertically assembled first LED elements;
wherein, in step (2), the solvent is configured such that the LED element dispersion solution forms droplets on the first electrode with a contact angle of 10 to 72 degrees.

2. The manufacturing method for an LED electrode assembly of claim 1, wherein the metal-binding group comprises at least one of a thiol group and an amine group.

3. The manufacturing method for an LED electrode assembly of claim 1, wherein the solvent has a surface tension of 26 mN/m or more measured at 20° C.

4. The manufacturing method for an LED electrode assembly of claim 1, wherein the surface of the first electrode on which the LED elements are mounted and the metal layer of the LED elements each independently include one or more selected from gold, silver, copper, and alloys including any one or more thereof.

5. The manufacturing method for an LED electrode assembly of claim 1, wherein the organic coupling linker in step (1) forms a self-assembled monolayer (SAM) on the first electrode surface.

6. The manufacturing method for an LED electrode assembly of claim 1, wherein the solvent has a vapor pressure of 10 mmHg or less at a temperature for performing step (3).

7. The manufacturing method for an LED electrode assembly of claim 1, further comprising, between steps (3) and (4), a heat treatment step performed at 200 to 600° C. for 3 to 10 minutes.

8. The manufacturing method for an LED electrode assembly of claim 1, further comprising, between steps (3) and (4), a cleaning step of cleaning the first electrode surface to remove misaligned LED elements from the first electrode surface.

9. An LED electrode assembly comprising:
a plurality of first electrodes spaced apart from each other;
a plurality of LED elements comprising first elements that have a metal electrode layer on one side in a thickness direction where layers are stacked, the metal electrode layer of a first LED element being vertically assembled to contact an upper surface of the first electrode; and
a second electrode electrically contacting upper portions of the vertically assembled LED elements,
wherein an organic coupling linker having metal-binding groups at both ends or a carbonized product of the organic coupling linker is provided between the first electrode and the metal electrode layer of the first LED elements contacting the first electrode.

10. The LED electrode assembly of claim 9, wherein the number of first LED elements among all LED elements positioned per 10,000 μm² in the first electrode is 40 or more, and the proportion of the first LED elements is 80% or more.

11. The LED electrode assembly of claim 9, wherein the LED element has a thickness of 0.5 to 3 μm and an area of a surface perpendicular to the thickness direction of 0.25 to 100 μm².

12. The LED electrode assembly of claim 10, wherein the number of first LED elements among all LED elements positioned per 10,000 μm² in the first electrode is 60 or more and a ratio of the first LED elements is 80% or more.

13. A light source comprising: a substrate having a plurality of sub-pixel sites; and an LED electrode assembly according to claim 9 disposed in each of the sub-pixel sites.
